(19) United States
(12) Patent Application Publication
(10) Pub. No.: US 2023/0298931 A1
(43) Pub. Date: Sep. 21, 2023

(54) METHOD FOR MANUFACTURING SEMICONDUCTOR DEVICE

(71) Applicant: WUHAN XINXIN SEMICONDUCTOR MANUFACTURING CO., LTD., Wuhan, Hubei (CN)

(72) Inventors: Tianyi ZHANG, Wuhan, Hubei (CN); Hao ZOU, Wuhan, Hubei (CN); Yan XIE, Wuhan, Hubei (CN)

(21) Appl. No.: 18/017,469

(22) PCT Filed: Sep. 18, 2020
(86) PCT No.: PCT/CN2020/116116

§ 371 Date: Jan. 23, 2023

(30) Foreign Application Priority Data
Jul. 31, 2020 (CN) 202010760314.7

(51) Int. Cl. H01L 21/768

(52) U.S. Cl. CPC H01L 21/76802; H01L 21/76831; H01L 21/76898; H01L 21/3065

(57) ABSTRACT

The present invention provides a method for fabricating a semiconductor device, including the steps of: providing a pre-processed device including a dielectric layer, a metal layer embedded in the dielectric layer and a first substrate covering the dielectric layer, the dielectric layer including a first dielectric layer, an etch stop layer and a second dielectric layer that are sequentially deposited, wherein the metal layer is embedded in the first dielectric layer, and the etch stop layer is located over the metal layer; forming a mask layer on the first substrate; with the mask layer serving as a mask, etching the first substrate by performing a first etching process to expose the dielectric layer; still with the mask layer as a mask, etching the exposed second dielectric layer by performing a second etching process, which stops at the etch stop layer, to form an opening; forming an isolation layer, which covers at least a sidewall of the opening; and etching away the first dielectric layer under the opening to expose the metal layer. In this way, the opening can be formed as a deep hole with reduced process complexity and cost by consecutively etching through the first substrate and the dielectric layer.

### TECHNICAL FIELD

The present invention relates to the field of integrated circuit fabrication technology and, in particular, to a method for fabricating a semiconductor device.

### BACKGROUND

Encouraged by the trend of semiconductor devices toward higher integration, wafer-level stacking has been developed based on 3D-IC technology to enable cheaper, faster, denser integration of chips. After stacked wafers are bonded together, it is necessary to form deep holes therein and fill a metal in the deep holes to achieve interconnection of the wafers. Such deep holes extend through substrates (e.g., silicon) and dielectric layers, and serve as connection for the wafers.

The deep holes consist of vertically connected through silicon vias (TSVs) extending through the silicon substrates and through dielectric vias (TDVs) extending through the dielectric layers. TSV is a new technique for creating vertical connections between chips and wafers to achieve interconnection of different chips. It allows for the creation of denser three-dimensional stacks.

A deep hole with a larger aspect ratio (e.g., >10:1) presents greater challenges in penetrating through silicon and dielectric layers. With the number of waters required to be bonded together becoming greater and greater, deep holes are required to be formed by penetrating through both thick silicon and thick dielectric layers, for example, in order to enable the bonding of 5 or more wafers together.

Currently, there is no available method suitable for mass production, which is capable of forming deep holes by consecutively etching through thick silicon and dielectric layers. Traditionally, deep holes were formed by alternately forming TSVs and TDVs in wafers to be stacked sequentially and then bonding the waters together so that the TSVs and TDVs are vertically connected. This approach is, however, time-consuming and costly because it involves the use of many reticles.

### SUMMARY OF THE INVENTION

It is an object of the present invention to provide a method for fabricating a semiconductor device, which is capable of forming an opening as a deep hole by consecutively etching through a first substrate and a dielectric layer, which are both thick.

The present invention provides a method for fabricating a semiconductor device, including the steps of:
providing a pre-processed device including a dielectric layer, a metal layer embedded in the dielectric layer and a first substrate covering the dielectric layer, wherein the dielectric layer includes a first dielectric layer, an etch stop layer and a second dielectric layer that are sequentially deposited, wherein the metal layer is embedded in the first dielectric layer, and the etch stop layer is located over the metal layer;
forming, on the first substrate, a mask layer from which a portion of the first substrate is exposed;
exposing the second dielectric layer by etching the first substrate through a first etching process with the mask layer serving as a mask;
forming an opening by etching the exposed second dielectric layer through a second etching process with the mask layer serving as a mask, wherein the second etching process stops at the etch stop layer;
forming an isolation layer covering at least a sidewall of the opening; and
exposing the metal layer by etching away the first dielectric layer under the opening.

Additionally, the first substrate may have a thickness greater than 50 μm.

Additionally, a time interval between the first etching process and the second etching process is from 2 h to 12 h.

Additionally, the mask layer may have a thickness of 10 μm to 20 μm.

Additionally, the isolation layer may have a thickness of 2000 Å to 3500 Å.

Additionally, the isolation layer may include a silicon oxide layer and/or a silicon nitride layer.

Additionally, the isolation layer may include a first silicon oxide layer, a silicon nitride layer and a second silicon oxide layer that are sequentially deposited over the sidewall of the opening.

Additionally, the first etching process may be accomplished by a plasma dry etching process using a reactant gas comprising SF₆ and C₄F₈, which is performed for a time duration of 800 s to 1000 s at a chamber pressure of 10 mTorr to 14 mTorr, a power level of 1000 W to 3000 W from an RF power supply and a bias voltage of 100 V to 900 V.

Additionally, the second etching process may be accomplished by a plasma dry etching process performed with process parameters including a chamber pressure of 10 mTorr to 14 mTorr, a CF₄ flow rate of 40 sccm to 60 sccm, a CHF₃ flow rate of 60 sccm to 80 sccm, a power level of 800 W to 1000 W from an RF power supply, a bias voltage of 170 V to 190 V and a time duration of 800 s to 1000 s.

Additionally, the step of exposing the metal layer by etching away the first dielectric layer under the opening may be accomplished by a plasma dry etching process performed with process parameters including a chamber pressure of 10 mTorr to 14 mTorr, a CF₄ flow rate of 40 sccm to 60 sccm, a CHF₃ flow rate of 60 sccm to 80 sccm, a power level of 500 W to 1000 W from an RF power supply, a bias voltage of 170 V to 190 V and a time duration of 400 s to 700 s.

Additionally, each of the first dielectric layer and the second dielectric layer may be oxide layer.

Additionally, the pre-processed device may further include a second substrate on which the dielectric layer is formed, wherein a wafer comprising the second substrate is a carrier wafer or a device wafer, with a wafer comprising the first substrate being a device wafer.

Compared with the prior art, the present invention offers the following benefits:

The present invention provides a method for fabricating a semiconductor device, including the steps of: providing a pre-processed device including a dielectric layer, a metal layer embedded in the dielectric layer and a first substrate covering the dielectric layer, wherein the dielectric layer includes a first dielectric layer, an etch stop layer and a second dielectric layer that are sequentially deposited, wherein the metal layer is embedded in the first dielectric layer, and the etch stop layer is located over the metal layer; forming a mask layer on the first substrate; exposing the second dielectric layer by etching the first substrate through a first etching process with the mask layer serving as a mask; forming an opening by etching the exposed second dielectric layer through a second etching process with the mask layer serving as a mask, wherein the second etching process stops at the etch stop layer; forming an isolation layer covering at least a sidewall of the opening; and exposing the metal layer by etching away the first dielectric layer under the opening. In this way, a deep hole can be formed by consecutively etching through the first substrate and the dielectric layer, which are both thick. This dispenses with the need to form a deep hole by forming TSVs and TDVs in different wafers and then bonding the wafers together. Therefore, a process with lower design complexity, increased universality and stability and reduced cost is achieved.

### BRIEF DESCRIPTION OF THE DRAWINGS

FIG. 1 is a flowchart of a method for fabricating a semiconductor device according to an embodiment of present invention.

FIGS. 2 to 6 are schematic diagrams showing steps in a method for fabricating a semiconductor device according to an embodiment of the present invention.

### DESCRIPTION OF REFERENCE NUMERALS IN DRAWINGS

11: Second Substrate; 12: Insulating Layer; 13: Metal Layer; 14: Dielectric Layer; 14a: First Dielectric Layer; 14b: Etch Stop Layer; 14c: Second Dielectric Layer; 15: First Substrate; 16: Mask Layer; 17: Isolation Layer.

### DETAILED DESCRIPTION

Embodiments of the present invention provide a method for fabricating a semiconductor device. The present invention will be described in greater detail below with reference to particular embodiments and the accompanying drawings. Advantages and features of the present invention will become more apparent from the following description. Note that the figures are provided in a very simplified form not necessarily drawn to exact scale and for the only purpose of facilitating easy and clear description of the embodiments.

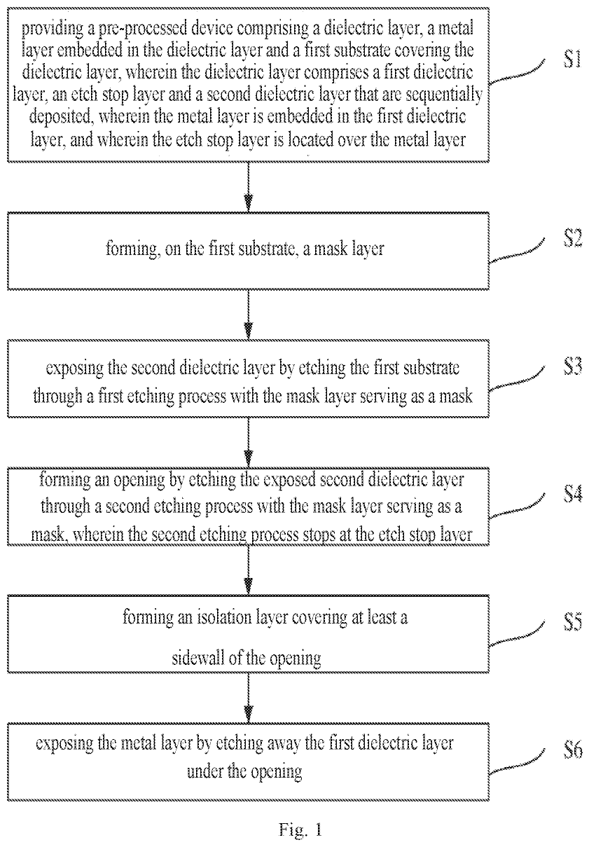

As shown in FIG. 1, a method for fabricating a semiconductor device according to an embodiment of the present invention includes:
providing a pre-processed device including a dielectric layer, a metal layer embedded in the dielectric layer and a first substrate covering the dielectric layer, wherein the dielectric layer includes a first dielectric layer, an etch stop layer and a second dielectric layer that are sequentially deposited, wherein the metal layer is embedded in the first dielectric layer, and the etch stop layer is located over the metal layer;
forming a mask layer over the first substrate;
with the mask layer serving as a mask, etching the first substrate to expose the second dielectric layer through a first etching process;
still with the mask layer serving as a mask, forming an opening by etching the exposed second dielectric layer through a second etching process, wherein the second etching process stops at the etch stop layer;
forming an isolation layer covering at least a sidewall of the opening; and
etching away the first dielectric layer under the opening to expose the metal layer.

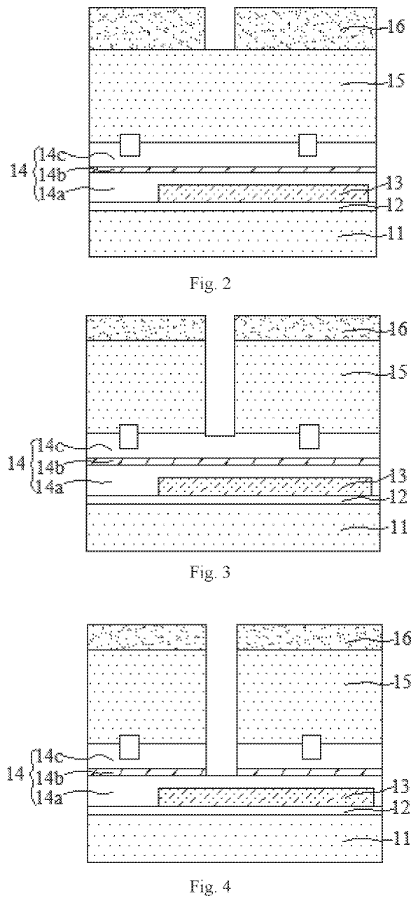

Steps in a method for fabricating a semiconductor device according to an embodiment of the present invention will be described in detail below with reference to FIGS. 2 to 6.

As shown in FIG. 2, a pre-processed device is provided, which includes a dielectric layer 14, a metal layer 13 embedded in the dielectric layer 14, and a first substrate 15 covering the dielectric layer 14. The dielectric layer 14 includes a first dielectric layer 14a, an etch stop layer 14b and a second dielectric layer 14c that are sequentially deposited. The metal layer 13 is embedded in the first dielectric layer 14a, and the etch stop layer 14b is located over the metal layer 13. As an example, the pre-processed device may further include a second substrate 11 below the dielectric layer 14. An insulating layer 12 may be formed over the second substrate 11, and the metal layer 13 may be located on the insulating layer 12. The metal layer 13 is embedded in the dielectric layer 14. The pre-processed device may be a stack of multiple wafers that are bonded together. A wafer comprising the second substrate 11 may be a carrier wafer or a device wafer. A wafer comprising the first substrate 15 may be, for example, a device wafer, and the second substrate 11 may be a stack of several wafers. The first substrate 15 may have a thickness that is, for example, greater than 50 μm. The first substrate 15 and the second substrate 11 may either contain identical components or not, depending on the actual requirements. In some embodiments, the first substrate 15 and/or the second substrate 11 may be semiconductor substrate(s) formed of any semiconductor material suitable for the semiconductor device (e.g., Si, SiC, SiGe, etc.) In other embodiments, each substrate may also be any of various composite substrates such as silicon-on-insulator (SOI) and silicon-germanium-on-insulator (SiGeOI) substrates. Those skilled in the art will appreciate that the invention is not limited to any type of substrate, and suitable choices can be made according to the requirements of actual applications. Various device components (not limited to those of semiconductor devices, not shown) may be formed in the substrates. Other layers or components, such as gate structures, contact holes, dielectric layers, metal bonding wires and through holes, may have been already formed in the substrates.

A mask layer 16 is formed over the first substrate 15. The mask layer 16 is provided therein with an opening above the metal layer 13. That is, the opening in the mask layer 16 is aligned with at least a portion of the metal layer 13. In particular, a passivation layer (not shown) may be further formed over the first substrate 15. In this case, the mask layer 16 is formed over the passivation layer. The mask layer 16 is formed of a material, which is, for example, photoresist, and has a thickness, for example, in the range of from 10 μm to 20 μm.

As shown in FIG. 3, with the mask layer 16 serving as a mask, a first etching process is performed to remove the first substrate 15 exposed in the opening. As a result, the dielectric layer 14 is exposed, and a through silicon via (TSV) is formed. Specifically, the first substrate 15 may have a thickness, which is, for example, greater than 50 and may be removed by dry etching. In one particular embodiment, a plasma dry etching process is employed, which uses a reactive gas containing SF₆ and C₄F₈ introduced into a plasma chamber set to a pressure of 10 mTorr to 14 mTorr and is performed for a time duration of 800 s to 1000 s at a power level of 1000 W to 3000 W from an RF power supply and a bias voltage of 100 V to 900 V. SF₆ reacts with silicon to produce volatile SiF₄. SiCₓF_{y}, as a by-product of the reaction of C₄F₈ with silicon, can protect a sidewall of the TSV. At least 5.5 μm of the mask layer 16 (e.g., photoresist) may remain from this process with acceptable morphology for later use.

As shown in FIG. 4, with the remaining portion of the mask layer 16 serving as a mask, a second etching process is performed to etch away a partial thickness of the dielectric layer exposed in the opening. The process stops at the etch stop layer 14b. In particular, a plasma dry etching process may be employed with process parameters including: a chamber pressure of 10 mTorr to 14 mTorr; a CF₄ flow rate of 40 sccm to 60 sccm; a CHF₃ flow rate of 60 sccm to 80 sccm; a power level of 800 W to 1000 W from an RF power supply; a bias voltage of a 170 V to 190 V; and a duration of time of 800 s to 1000 s. The etch stop layer 14b is, for example, a silicon nitride layer. Both the first dielectric layer 14a and the second dielectric layer 14c may be low dielectric constant (low-K) materials, such as analogous oxides containing the elements of silicon, oxygen, carbon and hydrogen, or silicate glass doped with fluorine ions, also known as fluorinated silicate glass (FSG). The first dielectric layer 14a exhibits good compactness and good surface coverage and can enhance adhesion between the etch stop layer 14b and the second substrate 11. Moreover, it can relieve stress in the etch stop layer 14b, preventing breakage of any chip on any wafer due to excessive stress in the etch stop layer 14b. As an example, the second dielectric layer 14c under the opening is etched, and the etching process stops at the etch stop layer 14b. The etching process may proceed in the second dielectric layer 14c to a depth of, for example, 4 μm to 10 μm. There may be a time interval of 2 h to 12 h between the first etching process and the second etching process, i.e., between the etching formation of the through dielectric via (TDV) and the TSV. In other words, 2 h to 12 h after the TSV is formed by etching away the first substrate 15 under the opening, the dielectric layer under the opening is etched and the process stops at the etch stop layer 14b. A time interval of 2 h would be sufficient for dissipation of electrostatic charge resulting from the etching to form the TSV. A time interval of 12 h would be sufficient for prevention of condensate defects caused by the reaction of by-products produced in step S3 with atmospheric water and moisture.

After that, the mask layer 16 is removed, and polymers produced in the etching processes are cleaned. The mask layer 16 is totally removed, together with electrostatic charge therein. In particular, the complete removal of the mask layer 16 (e.g., photoresist) may be accomplished by ashing with O₂, in which highly reactive oxygen atoms in oxygen plasma react with carbon, hydrogen and oxygen-based polymer compounds in the photoresist to generate CO, CO2, H2O, N₂ and other volatile substances. In this way, the photoresist is totally removed. O₂ and SF₆ may be mixed and introduced at a specified flow rate ratio. SF₆ may account for 8% to 20% of the total flow rate, which can effectively increase both the concentration of oxygen atoms in the plasma and the amount of activated photoresist, so as to increase the ashing efficiency of the photoresist and hence to ensure complete removal of the mask layer 16 and electrostatic charge therein. The process may be carried out for 100 s to 220 s at a chamber pressure of 40 mTorr to 60 mTorr, top electrode power of 1000 W to 1200 W, bottom electrode power of 30 W to 50 W, an O₂ flow rate of 180 sccm to 200 sccm and an SF₆ flow rate of 15 sccm to 35 sccm.

By-products produced during etching, such as polymers, on the sidewall and bottom of the opening and a top surface of the first substrate 15 are cleaned. In one particular embodiment, the cleaning is accomplished within 10 s to 20 s at a plasma chamber pressure of 25 mTorr to 35 mTorr, an etchant gas (e.g., containing argon (Ar)) flow rate of 170 sccm to 190 sccm and a power level of 390 W to 410 W from an RF power supply.

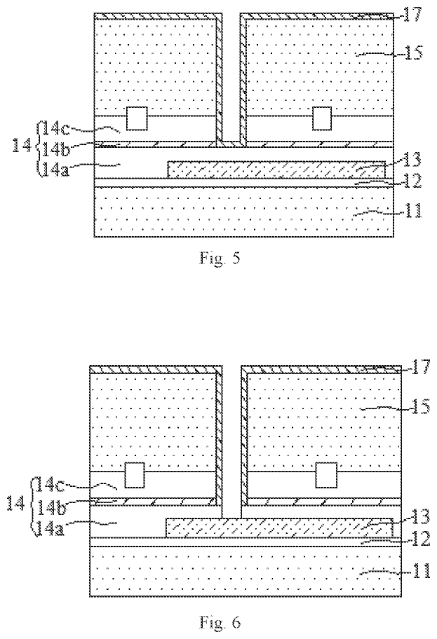

As shown in FIG. 5, an isolation layer 17 covering at least the sidewall and bottom of the opening is formed. The isolation layer 17 may further cover the top surface of the first substrate 15. The isolation layer 17 may have a thickness of, for example, 2000 Å to 3500 Å. The isolation layer 17 may be made of, for example, silicon dioxide (SiO₂). It may be formed by chemical vapor deposition (CVD), plasma enhanced chemical vapor deposition (PECVD) or another method. The isolation layer 17 may be a silicon dioxide-based material such as organosilicate glass (OSG), a silicon nitride-based material, a silicon oxynitride-based material, a silicon carbide-based material or a low-K dielectric.

On the one hand, during the subsequent dry etching process for exposing the metal layer 13, the isolation layer 17 can prevent diffusion, into the first substrate 15, of splashed particles generated from over-etching of the metal layer 13. On the other hand, the isolation layer can act as a barrier layer to prevent diffusion of the metal interconnect layer subsequently filled in the deep hole into the first substrate 15. Additionally, the isolation layer may include a silicon nitride layer, which is dense in texture and thus favorable to the prevention of diffusion. In other embodiments, the isolation layer 17 may be implemented as an ONO (silicon oxide/silicon nitride/silicon oxide) layer stack formed on the sidewall of the opening, in which the outer silicon oxide layer functions to protect the silicon nitride layer against etching, and the inner silicon oxide layer has good compactness and good surface coverage and functions to enhance adhesion between the silicon nitride layer and the first substrate 15 and to relieve stress in the silicon nitride layer, preventing breakage of any chip on any wafer due to excessive stress in the silicon nitride layer.

As shown in FIG. 6, the first dielectric layer 14a is etched away to expose the metal layer 13. In particular, a plasma dry etching process may be employed to open the underlying first dielectric layer 14a while guaranteeing a certain amount of loss, i.e., over-etching, of the metal layer 13. This is done to ensure success of the subsequent metal interconnect process. As an example, the isolation layer 17 may be reduced in thickness by smaller than 800 Å over the side wall of the opening and by smaller than 1500 Å over the first substrate 15. In addition, the first dielectric layer 14a removed from the bottom of the opening may have a thickness of 4000 Å. The etching power to expose the metal layer 13, for example, copper, is smaller than 1000 W. This can prevent arc discharge.

A CF-based gas may be used to etch the dielectric layer until the metal layer 13 is exposed, resulting in the formation of a deep hole. In one particular embodiment, a plasma dry etching process may be employed using an etchant gas containing fluorocarbons such as CF₄ at a flow rate of 40 sccm to 60 sccm and CHF₃ at a flow rate of 60 sccm to 80 sccm. The process may be performed for 400 s to 700 s at a plasma chamber pressure of 10 mTorr to 14 mTorr, a power level of 500 W to 1000 W from an RF power supply and a bias voltage of 170 V to 190 V. A metal, typically copper, is deposited in the deep hole to form a metal interconnect.

In summary, the present invention provides a method for fabricating a semiconductor device, including the steps of: providing a pre-processed device including a dielectric layer, a metal layer embedded in the dielectric layer and a first substrate covering the dielectric layer; the dielectric layer including a first dielectric layer, an etch stop layer and a second dielectric layer that are sequentially deposited, wherein the metal layer is embedded in the first dielectric layer, and the etch stop layer is located over the metal layer; forming a mask layer over the first substrate; with the mask layer serving as a mask, etching the first substrate until the second dielectric layer is exposed; still with the mask layer as a mask, etching the exposed second dielectric layer until the etch stop layer is reached, resulting in the formation of an opening; forming an isolation layer, which covers at least a sidewall of the opening; and etching away the first dielectric layer under the opening so that the metal layer is exposed. In this way, a deep hole can be formed by consecutively etching through the first substrate and the dielectric layer, which are both thick. This dispenses with the need to form a deep hole by forming TSVs and TDVs in different wafers and then bonding the wafers together. Therefore, a process with lower design complexity, increased universality and stability and reduced cost is achieved.

The embodiments disclosed herein are described in a progressive manner, with the description of each embodiment focusing on its differences from others. Reference can be made between the embodiments for their identical or similar parts. Since the method embodiments correspond to the device embodiments, they are described relatively briefly, and reference can be made to the device embodiments for details of them.

The description presented above is merely that of some preferred embodiments of the present invention and is not intended to limit the scope thereof in any sense. Any and all changes and modifications made by those of ordinary skill in the art based on the above teachings fall within the scope as defined in the appended claims.

1. A method for fabricating a semiconductor device, comprising the steps of:
providing a pre-processed device comprising a dielectric layer, a metal layer embedded in the dielectric layer and a first substrate covering the dielectric layer, wherein the dielectric layer comprises a first dielectric layer, an etch stop layer and a second dielectric layer that are sequentially deposited, wherein the metal layer is embedded in the first dielectric layer, and wherein the etch stop layer is located over the metal layer;
forming, on the first substrate, a mask layer from which a portion of the first substrate is exposed;
exposing the second dielectric layer by etching the first substrate through a first etching process with the mask layer serving as a mask;
forming an opening by etching the exposed second dielectric layer through a second etching process with the mask layer serving as a mask, wherein the second etching process stops at the etch stop layer;
forming an isolation layer covering at least a sidewall of the opening; and
exposing the metal layer by etching away the first dielectric layer under the opening.

2. The method of claim 1, wherein the first substrate has a thickness greater than 50 μm.

3. The method of claim 1, wherein a time interval between the first etching process and the second etching process is from 2 h to 12 h.

4. The method of claim 1, wherein the mask layer has a thickness of 10 μm to 20 μm.

5. The method of claim 1, wherein the isolation layer has a thickness of 2000 Å to 3500 Å.

6. The method of claim 1, wherein the isolation layer comprises a silicon oxide layer and/or a silicon nitride layer.

7. The method of claim 1, wherein the isolation layer comprises a first silicon oxide layer, a silicon nitride layer and a second silicon oxide layer that are sequentially deposited over the sidewall of the opening.

8. The method of claim 1, wherein the first etching process is accomplished by a plasma dry etching process using a reactant gas comprising SF₆ and C₄F₈, performed for a time duration of 800 s to 1000 s at a chamber pressure of 10 mTorr to 14 mTorr, a power level of 1000 W to 3000 W from an RF power supply and a bias voltage of 100 V to 900 V.

9. The method of claim 1, wherein the second etching process is accomplished by a plasma dry etching process performed with process parameters including a chamber pressure of 10 mTorr to 14 mTorr, a CF₄ flow rate of 40 sccm to 60 sccm, a CHF₃ flow rate of 60 sccm to 80 sccm, a power level of 800 W to 1000 W from an RF power supply, a bias voltage of 170 V to 190 V and a time duration of 800 s to 1000 s.

10. The method of claim 1, wherein the step of exposing the metal layer by etching away the first dielectric layer under the opening is accomplished by a plasma dry etching process performed with process parameters including a chamber pressure of 10 mTorr to 14 mTorr, a CF₄ flow rate of 40 sccm to 60 sccm, a CHF₃ flow rate of 60 sccm to 80 sccm, a power level of 500 W to 1000 W from an RF power supply, a bias voltage of 170 V to 190 V and a time duration of 400 s to 700 s.

11. The method of claim 1, wherein each of the first dielectric layer and the second dielectric layer is an oxide layer.

12. The method of claim 1, wherein the pre-processed device further comprises a second substrate on which the dielectric layer is formed, wherein a wafer comprising the second substrate is a carrier wafer or a device wafer, with a wafer comprising the first substrate being a device wafer.
